(19) United States
(12) Patent Application Publication
(10) Pub. No.: US 2025/0185165 A1
(43) Pub. Date: Jun. 5, 2025

(54) WIRING BOARD AND METHOD FOR MANUFACTURING WIRING BOARD

(71) Applicant: AOI ELECTRONICS CO., LTD., Kagawa (JP)

(72) Inventors: Takashi SUZUKI, Kagawa (JP); Ichiro KONO, Kagawa (JP); Yoshihiro KOMETANI, Kagawa (JP); Shoichi KOTANI, Kagawa (JP)

(21) Appl. No.: 18/845,879

(22) PCT Filed: Jan. 23, 2023
(86) PCT No.: PCT/JP2023/001894

§ 371 Date: Sep. 11, 2024

(30) Foreign Application Priority Data
Mar. 16, 2022 (JP) 2022-041769

(51) Int. Cl. H05K 1/11; H05K 1/02; H05K 1/18; H05K 3/12; H05K 3/40

(52) U.S. Cl. CPC H05K 1/113; H05K 1/0201; H05K 1/181; H05K 3/1258; H05K 3/4038; H05K 2201/09381; H05K 2201/09754; H05K 2201/098; H05K 2203/0582

(57) ABSTRACT

A wiring board includes: an external connection terminal provided at a bottom surface of the wiring board; an insulating layer around the external connection terminal; and a wiring layer that is layered on the insulating layer and is electrically connected with the external connection terminal through a via provided in the insulating layer; wherein the external connection terminal has a bottom conductive layer that constitutes a bottom surface of the external connection terminal with a plurality of protrusions protruding upward on a top surface of the bottom conductive layer.

### RELATED APPLICATIONS

The present application is a National Phase of International Application Number PCT/JP2023/001894 filed Jan. 23, 2023, which claims the benefit of priority from Japanese Patent Application No. 2022-041769, filed on Mar. 16, 2022.

### TECHNICAL FIELD

The present invention relates to a wiring board and a method for manufacturing a wiring board.

### BACKGROUND ART

In a semiconductor device having a board on which a semiconductor element such as an IC chip or an LED element is mounted, an external connection terminal that is visible at a back surface of the wiring board is used as an electrode for mounting. As a method for forming the external connection terminal, besides using a lead frame, a method using a thin film by plating is known. In a case where a thin film by plating is used, while the external connection terminal can be formed to be thin, there is a problem that the external connection terminal easily peels or falls off from the board. Thus, there have been proposed measures to form a protrusion having an eave-shaped cross section around a top edge of the external connection terminal (Patent Literature 1).

### CITATION LIST

### Patent Literature

Patent Literature 1: Japanese Patent Laid-Open Publication No. 2002-4077

### SUMMARY

### Technical Problem

An object of the present invention is to solve the problem that an external connection terminal peels or falls off in a wiring board having a primary surface on which a wiring layer is formed and a back surface on which the external connection terminal is provided.

### Solution to Problem

A wiring board of the present invention is a wiring board including: an external connection terminal provided at a bottom surface of the wiring board; an insulating layer around the external connection terminal; and a wiring layer that is layered on the insulating layer and is electrically connected with the external connection terminal through a via provided in the insulating layer, wherein the external connection terminal has a bottom conductive layer that constitutes a bottom surface of the external connection terminal with a plurality of protrusions protruding upward on a top surface of the bottom conductive layer.

In the wiring board, the via may have a larger diameter than the protrusions, and the plurality of protrusions may be arranged to surround the via.

In the wiring board, the via may include a plurality of columnar parts, and the plurality of protrusions may be arranged to surround the via.

In the wiring board, the plurality of protrusions may be arranged such that, when a distance from a center of the bottom conductive layer to an outer periphery of the bottom conductive layer is R, a distance between each protrusion and the outer periphery of the bottom conductive layer is equal to or smaller than R/3.

In the wiring board, a hole of the insulating layer in which the via is formed may have a rough inner surface.

In the wiring board, holes of the insulating layer in which the protrusions are formed may have rough inner surfaces.

In the wiring board, the protrusions may be electrically connected with the wiring layer.

In the wiring board, the protrusions may be 3 to 32 columnar members.

A method for manufacturing a wiring board of the present invention is a method for manufacturing a wiring board including an external connection terminal provided at a bottom surface of the wiring board, an insulating layer around the external connection terminal, and a wiring layer that is layered on the insulating layer and is electrically connected with the external connection terminal through a via provided in the insulating layer, the method including: an external connection terminal forming step of forming the external connection terminal on a supporting board; an insulating layer forming step of forming the insulating layer around the external connection terminal; a via forming step of forming the via that electrically connects the external connection terminal with the wiring layer; and a wiring layer forming step of forming the wiring layer on top of the insulating layer, wherein the external connection terminal forming step includes forming a bottom conductive layer that constitutes a bottom surface of the external connection terminal and forming a plurality of protrusions that protrude upward from a top surface of the bottom conductive layer.

### Advantageous Effects of Invention

According to the present invention, it is possible to solve the problem that an external connection terminal peels or falls off in a wiring board having a primary surface on which a wiring layer is formed and a back surface on which the external connection terminal is provided. In addition, it is possible to improve heat dissipation and heat resistance of the external connection terminal.

### BRIEF DESCRIPTION OF DRAWINGS

FIG. 1 is a cross-sectional view of a semiconductor device according to a first embodiment.

FIG. 2 is a plan view of a bottom conductive layer according to the first embodiment.

FIGS. 3A to 3D show diagrams explaining a method for manufacturing a wiring board according to the first embodiment.

FIGS. 4A to 4D show diagrams illustrating steps subsequent to those in FIGS. 3A to 3D.

FIGS. 5A to 5D show diagrams illustrating steps subsequent to those in FIGS. 4A to 4D.

FIGS. 6A to 6D show diagrams illustrating steps subsequent to those in FIGS. 5A to 5D.

FIGS. 7A to 7D show diagrams explaining a method for manufacturing a wiring board according to a second embodiment.

FIGS. 8A to 8C show diagrams illustrating steps subsequent to those in FIGS. 7A to 7D.

FIGS. 9A to 9C shows diagrams illustrating steps subsequent to those in FIGS. 8A to 8C.

FIG. 10 is a plan view of a bottom conductive layer according to the second embodiment.

FIGS. 11A and 11B show a cross-sectional view of a wiring board and a plan view of a bottom conductive layer according to a third embodiment.

FIG. 12 is a cross-sectional view of a semiconductor device showing a variation of the embodiments.

FIGS. 13A and 13B show a cross-sectional view explaining steps of manufacturing a conventional wiring board and a plan view of a bottom conductive layer thereof.

### DESCRIPTION OF EMBODIMENTS

Embodiments of the present invention will be described below with reference to the drawings. In the drawings to be described below, the shape, the size such as length, width, and thickness, and the ratio in length, width, and thickness of each member are shown differently from the actual shape, size, and ratio as appropriate to clarify the configuration of the invention. Thus, the shape, the size, and the ratio in length, width, and thickness of each member in the drawings should not be taken into consideration in comparison with the same element of the same member or the same element of another member.

### Conventional Example

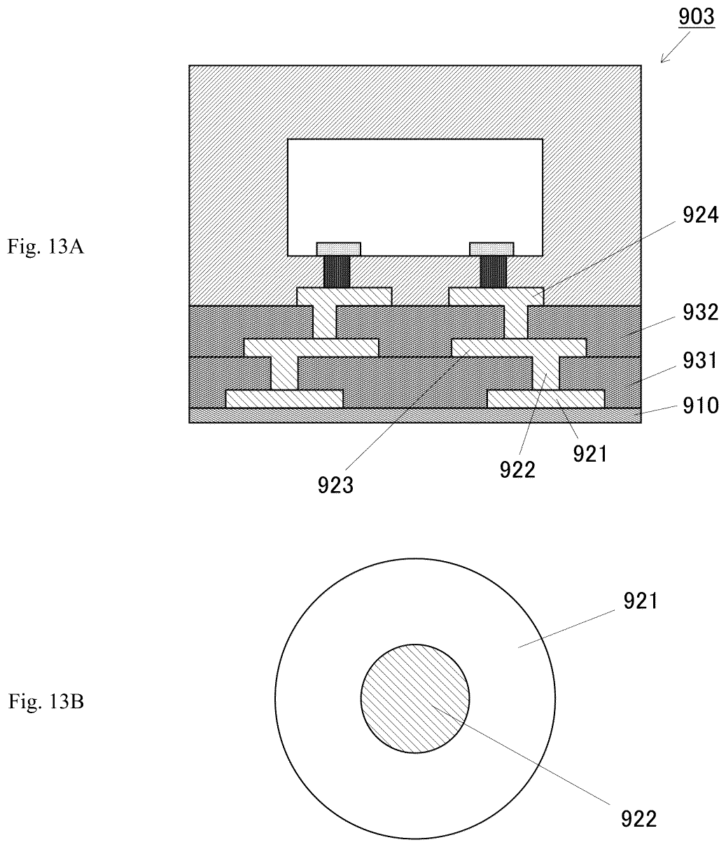

FIGS. 13A and 13B show a cross-sectional view explaining a conventional wiring board 903 and a plan view of a bottom conductive layer thereof. As illustrated in FIG. 13A, the wiring board 903 includes a first insulating layer 931 and a second insulating layer 932. At a bottom surface of the first insulating layer, a bottom conductive layer 921 constituting an external connection terminal is provided. The bottom conductive layer 921 is electrically connected with a wiring layer 923 through a via 922. FIG. 13B is a plan view of the bottom conductive layer 921 and the via 922. On a top surface of the second insulating layer 932, an upper wiring layer 924 that is connected with a semiconductor element is provided.

The above-described conventional wiring board 903, which is formed by laminating the wiring layers and the insulating layers on a supporting board 910, has an issue that the bottom conductive layer 921 peels off from the insulating layer 931 when peeling off the supporting board 910 and an issue that the bottom conductive layer 921 falls off after mounting.

It is presumed that these issues are caused by reduced adhesiveness between the insulating layer 931 and the bottom conductive layer 921 at the time of peeling off the supporting board 910 because the bottom conductive layer 921 is as thin as approximately 10 μm. In addition, it is also presumed that they are caused by interfacial peeling that occurs because of difference in heat resistance between the bottom conductive layer 921 and the insulating layer 931 resulting in expansion coefficient difference concentrated at the interface, and by peeling due to oxidation of the bottom conductive layer 921 progressing from a revealed surface of the bottom conductive layer 921, which is revealed in an opening at the time of opening a hole for the via 922, to a periphery thereof.

### First Embodiment

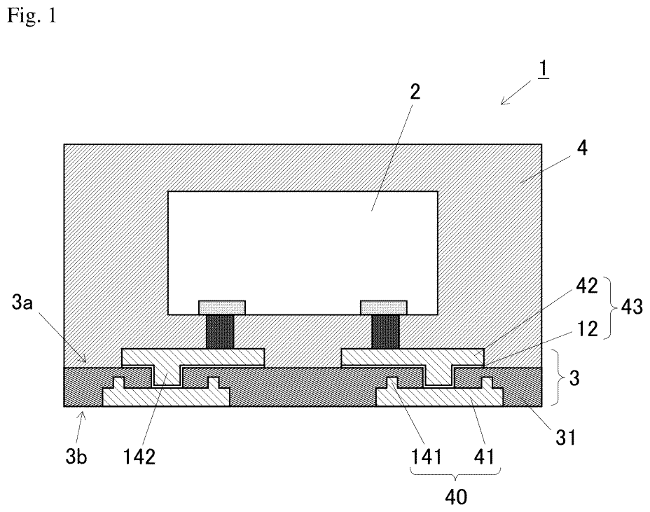

FIG. 1 is a view schematically illustrating a cross-sectional structure of a semiconductor device 1 according to a first embodiment. The semiconductor device 1 includes a semiconductor element 2 and a wiring board 3 on which the semiconductor element 2 is placed. The semiconductor element 2 is sealed with an insulating sealing resin 4. The wiring board 3 has a board primary surface 3a that is a surface on which the semiconductor element 2 is placed and a board back surface 3b that is an opposite side of the board primary surface 3a. On the board primary surface 3a, a wiring layer 43 is formed for electrical connection of the semiconductor element. The wiring layer 43 may have a multi-layered configuration including a plurality of metal layers. Although the face-down connection is illustrated as an example for the electrical connection of the semiconductor element with the wiring layer 43, wire bonding connection is also possible.

An external connection terminal 40 visible at the board back surface 3b of the wiring board 3 is a terminal for the semiconductor device 1 to be mounted onto a mounting board (not illustrated). The external connection terminal 40 is constituted by a bottom conductive layer 41 visible at the board back surface 3b and protrusions 141 formed on the bottom conductive layer 41. The bottom conductive layer 41 visible from the back surface 3b side and the board back surface 3b are in the same plane. The bottom conductive layer 41 is electrically connected with the wiring layer 43 by a via 142 formed in an insulating layer 31.

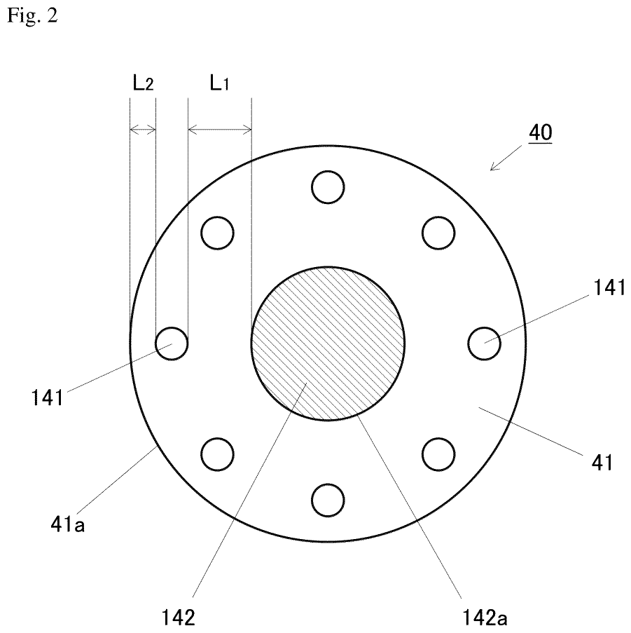

FIG. 2 shows the external connection terminal 40 as viewed from the board primary surface 3a side. In the present embodiment, as illustrated in FIG. 2, eight protrusions 141 protruding upward are arranged at equal intervals in a ring on a top surface of the bottom conductive layer 41. The via 142 is located at the center of the bottom conductive layer 41 and is surrounded by the eight protrusions 141. A plurality of the provided protrusions 141 increase adhesiveness between the external connection terminal 40 and the insulating layer 31, thereby improving resistance of the external connection terminal 40 to peeling and falling off.

The positions, the number, and the thickness of the protrusions 141 can be adjusted depending on desired adhesion strength. It is disclosed that the number of the protrusions 141 can be any number more than one, and preferably, 3 to 32 or 4 to 24. Results of a comparative experiment in which four to twelve protrusions 141 were provided confirmed that a larger number of protrusions 141 exhibit greater joint strength (shear test value).

It was also confirmed that protrusions 141 provided near an outer periphery 41a of the bottom conductive layer exhibit greater joint strength (shear test value). That is, the protrusions 141 are preferably arranged such that a distance L1 from an outer periphery 142a of the via to a protrusion 141 is larger than a distance L2 from the outer periphery 41a of the bottom conductive layer to the protrusion 141.

From another point of view, the protrusions 141 are arranged such that, when a distance (a radius in the example of FIG. 2) from the center of the bottom conductive layer 41 to the outer periphery 41a of the bottom conductive layer is R, for example, the distance L2 between each protrusion 141 and the outer periphery 41a of the bottom conductive layer is preferably equal to or smaller than R/3, or more preferably than R/4.

It was also confirmed that, as long as arrangement conditions of protrusions 141 are the same, protrusions 141 with a larger diameter exhibit further greater joint strength (shear test value).

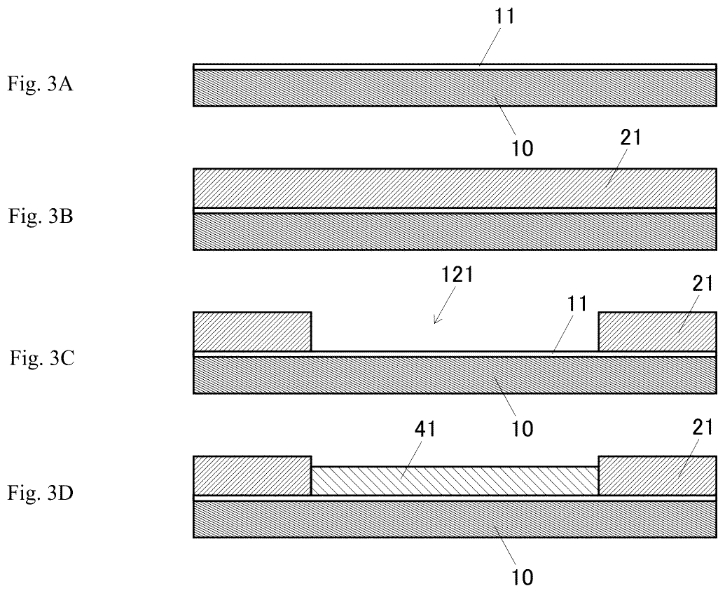

Next, a method for manufacturing the wiring board 3 illustrated in FIG. 1 will be described. FIGS. 3A to 3D through 6A to 6D show cross-sectional views illustrating an example of the manufacturing method. Although steps of manufacturing a part of a wiring board are shown in FIGS. 3A to 3D through 6A to 6D, in practice, a wiring board with a size depending on a required wiring pattern is created on a supporting board 10.

In a step illustrated in FIG. 3A, a seed layer 12 is formed on the supporting board 10. The supporting board 10 of the present embodiment is a rectangular board made of glass or copper and, for the seed layer 11, titanium (Ti) is used, for example.

In a step illustrated in FIG. 3B, a photoresist 21 is formed on the entire top surface of the seed layer 11. The photoresist 21 is formed by laminating, for example, a dry film type photosensitive resist film by a laminator. The photoresist 21 is thicker than the bottom conductive layer 41 to be able to accommodate thickness tolerance, and has a thickness of, for example, 20 to 40 μm.

In a step illustrated in FIG. 3C, the photoresist 21 is exposed using a photomask (not illustrated). The photomask has a non-transparent portion in a shape of a pattern corresponding to the shape of the bottom conductive layer 41, and a transparent portion around the non-transparent portion. The exposure using the photomask causes a portion of the photoresist 21 corresponding to the transparent portion to react with light.

Subsequently, the photomask is removed and development processing is performed on the photoresist 21 to remove the non-reacted portion from the photoresist 21. As a result, an opening 121 in the shape of the pattern corresponding to the shape of the bottom conductive layer 41 is formed in the photoresist 21.

In a step illustrated in FIG. 3D, on the revealed area of the seed layer 11 at a bottom of the opening 121 of the photoresist 21, the bottom conductive layer 41 is formed by electrolytic plating. The metal used for the electrolytic plating is, for example, Cu. The thickness of the bottom conductive layer 41 is, for example, 10 to 30 μm. Thereafter, the photoresist 21 is removed.

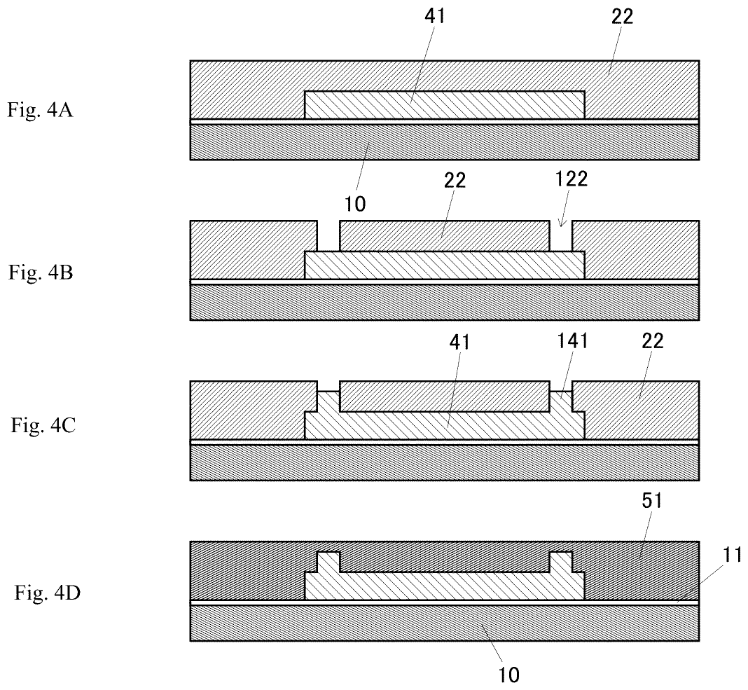

In a step illustrated in FIG. 4A, a photoresist 22 is formed on the entire top surface of the bottom conductive layer 41. The photoresist 22 is formed by laminating a dry film type photosensitive resist film by a laminator and then processing it with light. The photoresist 22 is thicker than the protrusions 141 to be able to accommodate thickness tolerance, and has a thickness of, for example, 13 to 22 μm.

In a step illustrated in FIG. 4B, protrusion holes 122 are formed by laser ablation or lithography at positions where the protrusions 141 are to be formed. Thus, portions of the bottom conductive layer 41 where the protrusions 141 are to be formed are revealed through the protrusion holes 122. In the present embodiment, eight protrusion holes 122 are formed at positions corresponding to the protrusions 141 illustrated in FIG. 2. The protrusion holes 122 have a uniform diameter smaller than that of a via hole 151 to be described later, for example, a diameter of 10 to 100 μm.

In a step illustrated in FIG. 4C, on top surfaces of the revealed areas of the bottom conductive layer 41 at bottoms of the protrusion holes 122 formed in FIG. 4B, the protrusions 141 are formed by electrolytic plating. In order to ensure insulation from the wiring layer 43, the thickness of the protrusions 141 is preferably equal to or smaller than the thickness of the via 142, for example, 3 to 30 μm, and preferably, 5 to 20 μm. Thereafter, the photoresist 22 is removed. It should be noted that the protrusions 141 may have a thickness to reach the wiring layer 43 but, in this case, there is a restriction on a pattern shape of the wiring layer 43.

In a step illustrated in FIG. 4D, an insulating layer 51 is formed by laminating an insulating film by a laminator. The insulating layer 51 has a thickness that can ensure insulation between the protrusions 141 and the wiring layer 43 and is, for example, 30 to 40 μm.

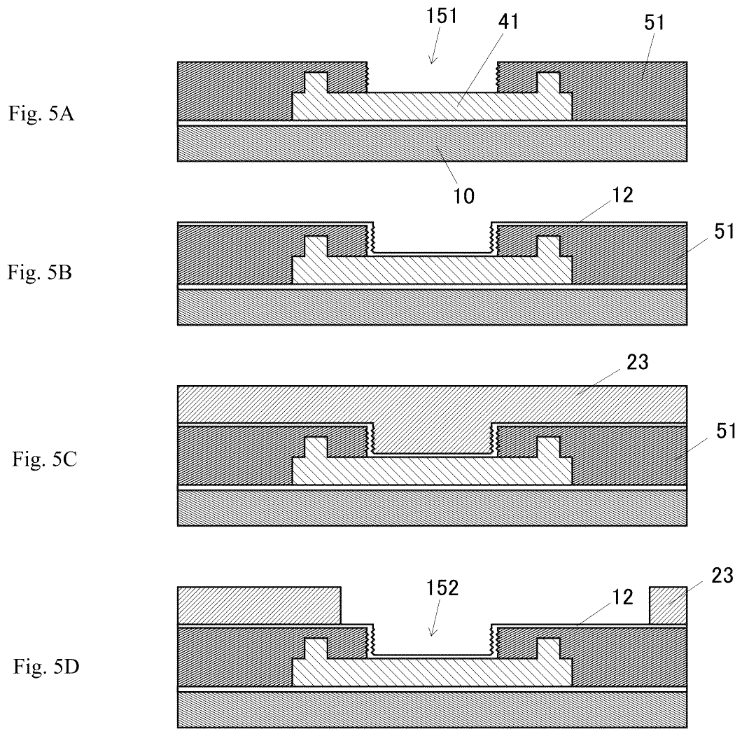

In a step illustrated in FIG. 5a, the via hole 151 is formed by laser ablation in which laser light is emitted from laser equipment, not illustrated, to a predetermined position of the insulating layer 51 to locally evaporate the insulating layer 51. The via hole 151 has, for example, a diameter of 50 to 200 μm and a depth of 10 to 50 μm. An inner surface of the via hole 151 becomes rough due to an effect of the laser light irradiation.

In a step illustrated in FIG. 5B, a seed layer 12 is formed on a top surface of the area of the bottom conductive layer 41 revealed in the via hole 151, a top surface of the insulating layer 51, and the inner surface of the via hole 151. The seed layer 12 is formed of a metal film with such a thickness that leaves irregularities resulting from the rough inner surface of the via hole 151. For example, a Cu film with a thickness of 1 μm or less is formed by non-electrolytic plating.

In a step illustrated in FIG. 5C, a photoresist 23 is formed on the entire top surface of the seed layer 12. The photoresist 23 is formed by laminating a dry film type photosensitive resist film by a laminator and then processing it with light.

Subsequently, the photoresist 23 is exposed using a photomask (not illustrated). The photomask has a non-transparent portion in a shape of a pattern corresponding to the shape of the wiring layer 43, and a transparent portion around the non-transparent portion. The exposure using the photomask causes a portion of the photoresist 23 corresponding to the transparent portion to react with light.

In a step illustrated in FIG. 5D, the photomask is removed and development processing is performed on the photoresist 23 to remove the non-reacted portion from the photoresist 23. As a result, only a portion where the wiring layer 43 is to be formed is removed from the photoresist 23, and an opening 152 in which the seed layer 12 is revealed is formed.

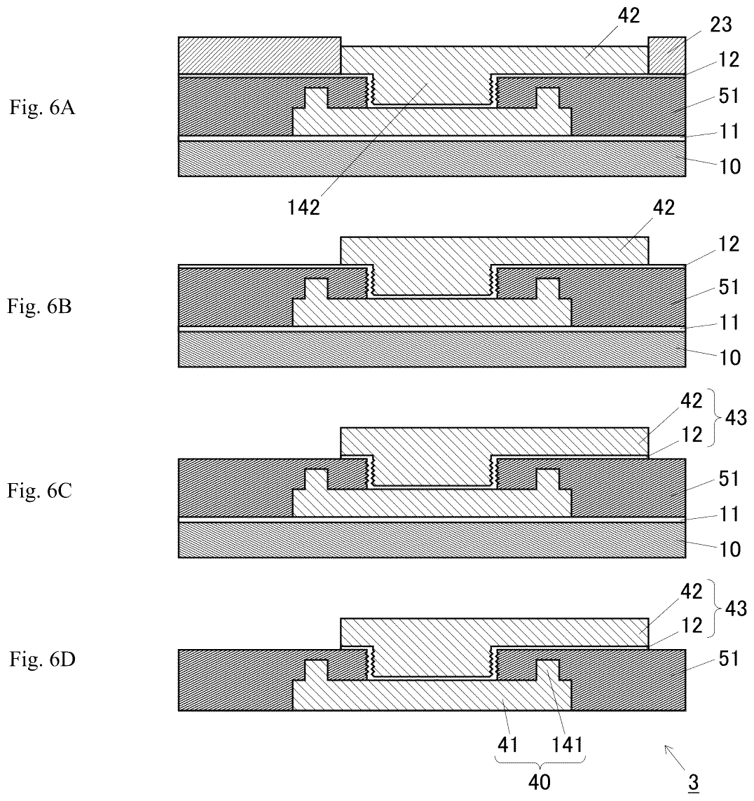

In a step illustrated in FIG. 6A, on the area of the seed layer 12 not covered by the photoresist 23, a metal layer 42 and the via 142 are formed by electrolytic plating utilizing the seed layer 12.

In a step illustrated in FIG. 6B, the photoresist 23 is removed. Thus, the area of the seed layer 12 that has been covered by the photoresist 23 is revealed.

In a step illustrated in FIG. 6C, the area of the seed layer 12 revealed in the previous step and not covered by the metal layer 42 is removed by etching. This completes the formation of the wiring layer 43 with each pattern electrically independent.

In a step illustrated in FIG. 6D, the supporting board 10 is peeled off from the wiring board 3. The peeling process may be performed by peeling or, in a case where the supporting board 10 is metal such as copper, the supporting board 10 may be removed by dissolution. Furthermore, the seed layer 11 remaining on a bottom surface of the supporting board 10 is removed by etching, thereby completing the wiring board 3.

Alternatively, after the step of FIG. 6C, an electronic component such as a semiconductor element may be connected to the wiring layer 43, and then the electronic component and the like may be sealed with an insulating sealing resin before the step of FIG. 6D.

In the wiring board 3 of the first embodiment described above, since a plurality of the protrusions 141 sticking upward from the bottom conductive layer 41 are buried in the insulating layer 51 like spikes, firm adhesion of the external connection terminal 40 to the insulating layer 51 is achieved. In addition, a plurality of the provided protrusions 141 improve heat dissipation and heat resistance of the external connection terminal 40.

Therefore, according to the wiring board 3 of the first embodiment, the issues of peeling and falling off of the external connection terminal 40 can be solved.

### Second Embodiment

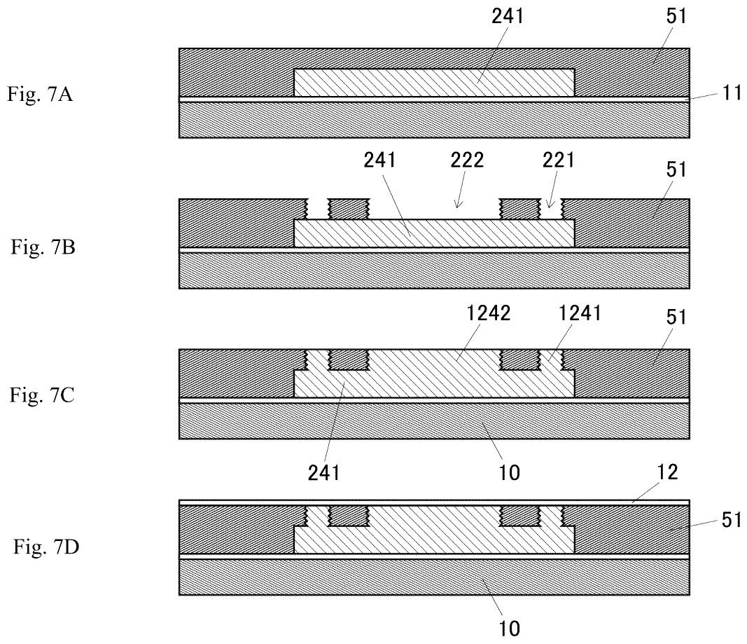

A method for manufacturing a wiring board 203 of a second embodiment will be described with reference to FIGS. 7A to 7D through 9A to 9C. The components that are similar to those in the first embodiment are denoted by the same reference signs as those in the first embodiment, and explanations thereof are omitted.

In the method for manufacturing the wiring board 203 of the second embodiment, steps prior to those in FIGS. 7A to 7D are the same as the steps illustrated in FIGS. 3A to 3D of the first embodiment, and thus will not be described.

In a step illustrated in FIG. 7A, an insulating layer 51 is formed by laminating an insulating film by a laminator. The insulating layer 51 has a thickness that can ensure the thickness of protrusions 1241 and a via 1242 and is, for example, 20 to 40 μm.

In a step illustrated in FIG. 7B, laser light is emitted from laser equipment, not illustrated, to predetermined positions of the insulating layer 51 to form protrusion holes 221 and a via hole 222. The protrusion holes 221 have uniform dimensions, for example, a diameter of 10 to 100 μm and a depth of 10 to 50 μm. The via hole 222 has a larger diameter than the protrusion holes 221, for example, a diameter of 50 to 200 μm, and has the same depth as the protrusion holes 221.

Inner surfaces of the via hole 222 and the protrusion holes 221 become rough due to an effect of the laser irradiation.

In a step illustrated in FIG. 7C, on the revealed areas of a bottom conductive layer 241 at bottoms of the protrusion holes 221 and the via hole 222, the protrusions 1241 and the via 1242 are formed by electrolytic plating. The metal used for the electrolytic plating is, for example, Cu. Since the inner surfaces of the via hole 222 and the protrusion holes 221 are rough due to the effect of the laser irradiation, not only the via 1242 but also the protrusions 1241 are strongly adhered to the insulating layer 51, thereby enhancing resistance to peeling and falling off.

In a step illustrated in FIG. 7D, a seed layer 12 is formed on top surfaces of the protrusions 1241, the via 1242, and the insulating layer 51. A method for forming the seed layer 12 is the same as that of the first embodiment.

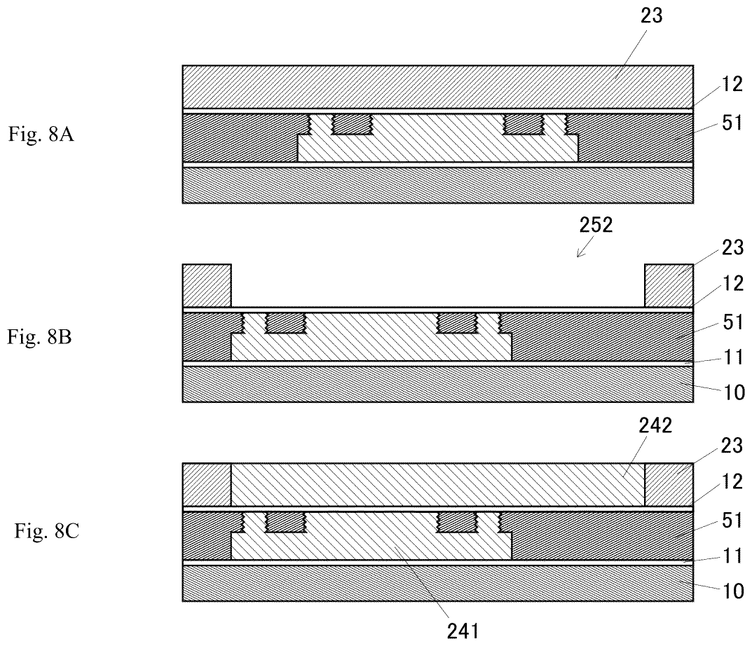

In a step illustrated in FIG. 8A, a photoresist 23 is formed on the entire top surface of the seed layer 12. A method for forming the photoresist 23 is the same as that of the first embodiment.

Subsequently, the photoresist 23 is exposed using a photomask (not illustrated). The photomask has a non-transparent portion in a shape of a pattern corresponding to the shape of a wiring layer 243, and a transparent portion around the non-transparent portion. The exposure using the photomask causes a portion of the photoresist 23 corresponding to the transparent portion to react with light.

In a step illustrated in FIG. 8B, the photomask is removed and development processing is performed on the photoresist 23 to remove the non-reacted portion from the photoresist 23. As a result, only a portion where the wiring layer 243 is to be formed is removed from the photoresist 23, and an opening 252 in which the seed layer 12 is revealed is formed.

In a step illustrated in FIG. 8C, on the area of the seed layer 12 not covered by the photoresist 23, a metal layer 242 is formed by electrolytic plating using the seed layer 12.

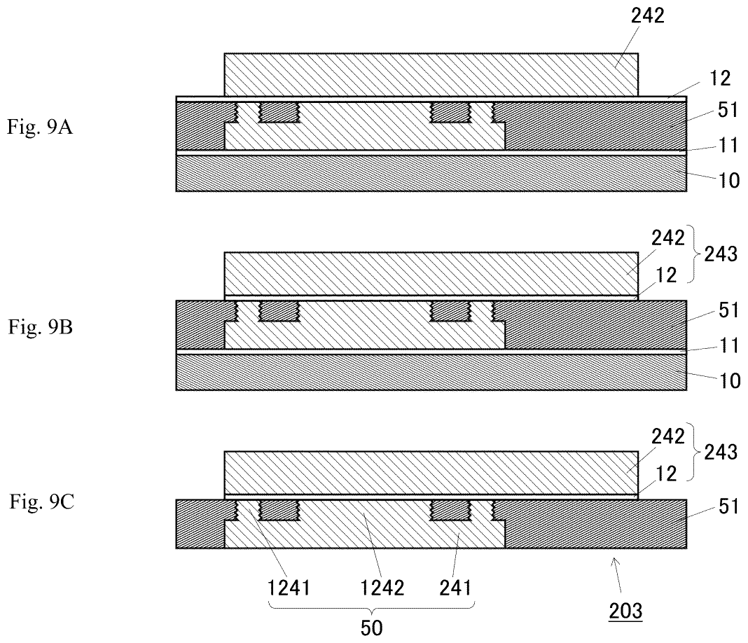

In a step illustrated in FIG. 9A, the photoresist 23 is removed. Thus, the area of the seed layer 12 that has been covered by the photoresist 23 is revealed.

In a step illustrated in FIG. 9B, the area of the seed layer 12 revealed in the previous step and not covered by the metal layer 242 is removed by etching. This makes each pattern in the wiring layer 243 electrically independent and completes the formation of the wiring layer 243.

In a step illustrated in FIG. 9C, the supporting board 10 is peeled off from the wiring board 203. The peeling process may be performed by peeling or, in a case where the supporting board 10 is metal such as copper, the supporting board 10 may be removed by dissolution. Furthermore, the seed layer 11 remaining on a bottom surface of the supporting board 10 is removed by etching, thereby completing the wiring board 203.

Alternatively, after the step of FIG. 9B, an electronic component such as a semiconductor element may be connected to the wiring layer 243, and then the electronic component and the like may be sealed with an insulating sealing resin before the step of FIG. 9C.

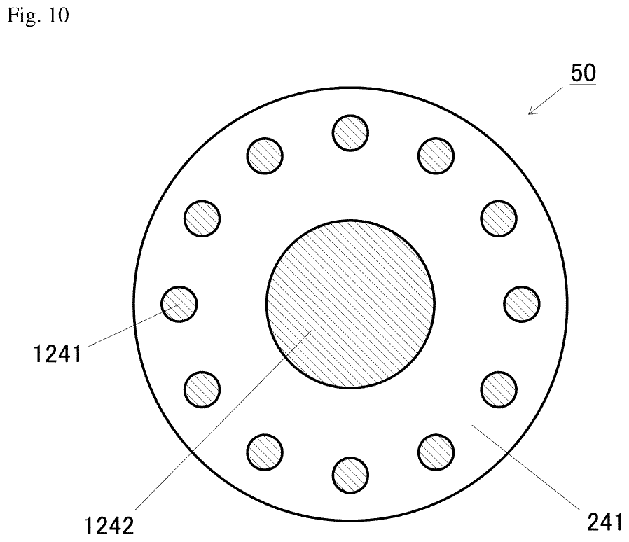

FIG. 10 shows an external connection terminal 50 as viewed from the primary surface side of the wiring board 203. In the present embodiment, as illustrated in FIG. 10, twelve protrusions 1241 protruding upward are arranged at equal intervals in a ring on a top surface of the bottom conductive layer 241. The via 1242 is located at the center of the bottom conductive layer 241 and is surrounded by the twelve protrusions 1241. Also in the second embodiment, a plurality of the provided protrusions 1241 increase adhesiveness between the external connection terminal 50 and the insulating layer 51, thereby improving resistance of the external connection terminal 50 to peeling and falling off. Note that the number of protrusions 1241 is not limited to twelve as illustrated and can be any number more than one, as with the case of the first embodiment.

In the wiring board 203 of the second embodiment described above, a plurality of the protrusions 1241 sticking upward from the bottom conductive layer 241 are joined to the wiring layer 243, and not only the inner surface of the via hole 222 but also the inner surfaces of the protrusion holes 221 are rough due to the effect of the laser irradiation. Therefore, adhesiveness between the external connection terminal 50 and the insulating layer 51 is increased and resistance to peeling and falling off is further strengthened. Furthermore, the plurality of the protrusions 1241 serve as heat dissipation paths between the wiring layer 243 and the bottom conductive layer 241, thereby improving heat dissipation of the semiconductor device.

### Third Embodiment

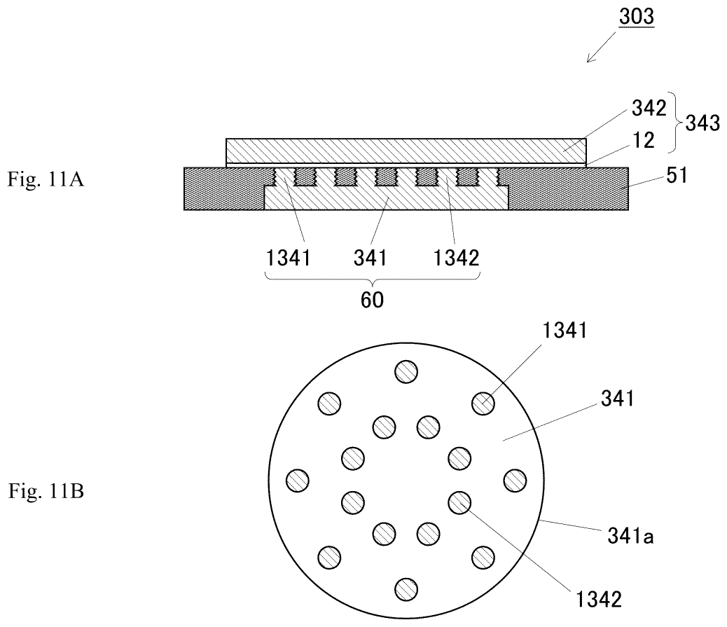

A wiring board 303 of a third embodiment will be described with reference to FIGS. 11A and 11B.

The wiring board 303 of the third embodiment is different from the wiring board 203 of the second embodiment in that, instead of a single large-diameter via, a plurality of via parts with a smaller diameter than the via of the second embodiment are provided. Hereinafter, differences from the second embodiment will be mainly described and common points will not be described.

The wiring board 303 of the third embodiment includes, on a bottom conductive layer 341, eight protrusions 1341 arranged along a first circle, and eight via parts 1342 arranged along a second circle with a smaller diameter than the first circle (see FIG. 11B). The eight protrusions 1341 arranged along the first circle are arranged at equal intervals and closer to an outer periphery 341a of the bottom conductive layer than the via parts 1342. The eight via parts 1342 arranged along the second circle are arranged at equal intervals near the center of the bottom conductive layer 341. Note that the number of protrusions 1341 and the number of via parts 1342 are not limited to eight as illustrated and are each disclosed to be, for example, 3 to 24. The number of protrusions 1341 and the number of via parts 1342 do not have to be the same, and one may be more than the other.

As illustrated in FIG. 11A, a wiring layer 343 constituted by a patterned metal layer 342 and a seed layer 12 is joined to the protrusions 1341 and the via parts 1342 at a bottom of the wiring layer 343, so that the wiring layer 343 is electrically connected with the bottom conductive layer 341 through the protrusions 1341 and the via parts 1342. In the third embodiment, since the protrusions 1341 and the via parts 1342 serve as the electrical connection between the wiring layer 343 and the bottom conductive layer 341, the total cross-sectional area of the protrusions 1341 and the via parts 1342 is preferably at least as large as the cross-sectional area of the large-diameter via used as the via 142 in FIG. 2.

From a point of view of enhancing joint strength of the protrusions 1341, the protrusions 1341 are preferably provided near the outer periphery 341a of the bottom conductive layer. For example, the protrusions 1341 are arranged such that, when a distance (a radius in the example of FIG. 2) from the center of the bottom conductive layer 341 to the outer periphery 341a of the bottom conductive layer is R, the distance between each protrusion 1341 and the outer periphery 341a of the bottom conductive layer is preferably equal to or smaller than R/3, or more preferably than R/4.

In the wiring board 303 of the third embodiment described above, an external connection terminal 60 is electrically connected with the wiring layer 343 by a plurality of the protrusions 1341 and a plurality of the protrusions 1342, and inner surfaces of all protrusion holes are made rough. Therefore, adhesiveness to the insulating layer 51 is strong and resistance to peeling and falling off is high.

### Variation

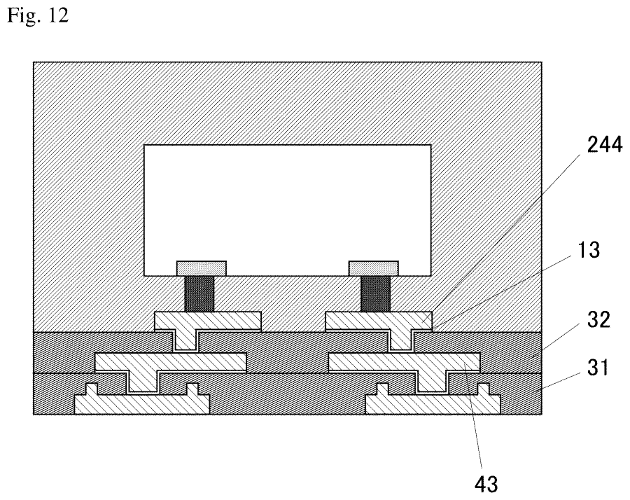

In the wiring boards of the first to third embodiments, a configuration is shown where only one wiring layer is electrically connected with an external connection terminal. However, as illustrated in FIG. 12, a further upper wiring layer 244 may be formed on an insulating layer 32 that is laminated on the wiring layer 43. A method for forming the upper wiring layer 244 is the same as the method for manufacturing the via 142 and the wiring layer 43 in the first embodiment, and thus will not be described. Although FIG. 12 illustrates a configuration where the insulating layer 32 and the upper wiring layer 244 are formed on top of the wiring board 3 of the first embodiment, the insulating layer 32 and the upper wiring layer 244 can be formed by the same method alternatively on top of the wiring board (203, 303) of the second or third embodiment. Furthermore, a wiring board may have more wiring layers by repeating the same manufacturing method.

Although preferred embodiment examples of the present invention have been described above, the technical scope of the present invention is not limited to the descriptions of the above embodiment examples. Various alterations and modifications can be applied to the above embodiment examples, and such altered or modified modes also fall within the technical scope of the present invention. For example, the protrusions and the via each have a columnar shape with a circular cross section in the above embodiment examples, but they may have a columnar shape with a polygonal cross section or the like.

1-9. (canceled)

10. A wiring board comprising:
an external connection terminal of which bottom surface is visible;
an insulating layer around the external connection terminal, the insulating layer consisting of a single layer; and
a wiring layer that is layered on the insulating layer and is electrically connected with the external connection terminal through a via provided in the insulating layer;
wherein the bottom surface of the external connection terminal and a bottom surface of the insulating layer are in a same plane, and
the external connection terminal has a bottom conductive layer that constitutes the bottom surface of the external connection terminal, the external connection terminal including a plurality of columnar protrusions formed to protrude upward into the insulating layer on a top surface of the bottom conductive layer.

11. The wiring board according to claim 10, wherein the via has a larger diameter than the protrusions, and
the plurality of protrusions are arranged to surround the via.

12. The wiring board according to claim 10, wherein the via includes a plurality of columnar parts, and
the plurality of protrusions are arranged to surround the via.

13. The wiring board according to claim 10, wherein the plurality of protrusions are arranged such that, when a distance from a center of the bottom conductive layer to an outer periphery of the bottom conductive layer is R, a distance between each protrusion and the outer periphery of the bottom conductive layer is equal to or smaller than R/3.

14. The wiring board according to claim 10, wherein the via is formed in a via hole formed in the insulating layer and the via hole has a rough inner surface.

15. The wiring board according to claim 10, wherein the protrusions are formed in protrusion holes formed in the insulating layer and the protrusion holes have rough inner surfaces.

16. The wiring board according to claim 10, wherein the protrusions are formed in protrusion holes formed in the insulating layer and the bottom conductive layer is electrically connected with the wiring layer through the protrusions.

17. The wiring board according to claim 10, wherein the protrusions are 3 to 32 columnar members.

18. The wiring board according to claim 10, wherein the wiring layer is formed on a top surface of the insulating layer, and
the plurality of protrusions are formed to have a thickness not reaching the wiring layer.

19. A method for manufacturing a wiring board including an external connection terminal of which bottom surface is visible, an insulating layer around the external connection terminal, and a wiring layer that is layered on the insulating layer and is electrically connected with the external connection terminal through a via provided in the insulating layer, the method comprising:
an external connection terminal forming step of forming the external connection terminal on a supporting board;
an insulating layer forming step of forming the insulating layer around the external connection terminal, the insulating layer having a bottom surface in a same plane as the bottom surface of the external connection terminal and consisting of a single layer;
a via forming step of forming the via that electrically connects the external connection terminal with the wiring layer; and
a wiring layer forming step of forming the wiring layer on top of the insulating layer;
wherein the method further comprises, after forming a bottom conductive layer that constitutes the bottom surface of the external connection terminal, a step of forming a plurality of columnar protrusions that protrude upward into the insulating layer from a top surface of the bottom conductive layer.

20. The method for manufacturing the wiring board according to claim 19, wherein the method comprises, after forming the bottom conductive layer that constitutes the bottom surface of the external connection terminal, steps of forming a photoresist layer that covers the bottom conductive layer, forming protrusion holes in the photoresist layer, and forming the plurality of protrusions in the protrusion holes.

21. The method for manufacturing the wiring board according to claim 19, wherein, after forming the insulating layer, protrusion holes of which inner surfaces are rough are formed in the insulating layer, and the protrusions are formed in the protrusion holes.

22. The method for manufacturing the wiring board according to claim 19, wherein the via forming step includes forming a via hole of which inner surface is rough in the insulating layer, and forming the via in the via hole.
